(19) United States
(12) Patent Application Publication
(10) Pub. No.: US 2018/0366649 A1
(43) Pub. Date: Dec. 20, 2018

(54) MASK SHEET, VAPOR DEPOSITION MASK, AND METHOD FOR MANUFACTURING DISPLAY PANEL

(71) Applicant: Sharp Kabushiki Kaisha, Sakai City, Osaka (JP)

(72) Inventor: Koji YAMABUCHI, Sakai City (JP)

(21) Appl. No.: 16/062,640

(22) PCT Filed: Sep. 14, 2016
(86) PCT No.: PCT/JP2016/077185

§ 371 Date: Jun. 15, 2018

(51) Int. Cl. H01L 51/00; C23C 14/04; C23C 14/24; H01L 51/56

(52) U.S. Cl. CPC H01L 51/0011; C23C 14/042; H01L 27/3244; H01L 51/001; H01L 51/56; C23C 14/24

(57) ABSTRACT

A mask sheet for vapor deposition having a first direction (D1) as a longitudinal direction, the mask sheet including a grippable first side end portion (G1); and an intermediate portion (M) with a plurality of through-holes, wherein the mask sheet includes, between the first side end portion and the intermediate portion, a first narrow portion (K1) having a width (Wk) which is a length in a second direction (D2) orthogonal to the first direction and smaller than the intermediate portion, or two edge patterns having a thickness smaller than a maximum thickness of the intermediate portion along two edges facing each other in the second direction.

### TECHNICAL FIELD

The disclosure relates to a mask sheet for vapor deposition and the like.

### BACKGROUND ART

In the process of manufacturing Organic Light-Emitting Diode (OLED) panels, for example, an organic material pattern corresponding to a plurality of through-holes is formed by depositing an organic material on a substrate through a vapor deposition mask with a plurality of through-holes.

In the vapor deposition process, a plurality of mask sheets are fixed to a frame body (frame) for use. In particular, position alignment of the vapor deposition mask with respect to the frame body is performed in a state where tension is applied to the mask sheet, and the mask sheet is welded to the frame body (see PTL 1).

### CITATION LIST

### Patent Literature

PTL 1: JP 2015-127446 A (Publication Date: Jul. 9th, 2015)

### SUMMARY

### Technical Problem

The inventors found that when the tension state of the vapor deposition mask at the time of aligning the vapor deposition mask with respect to the frame body is different from the tension state of the vapor deposition mask after welding, the through-holes of the vapor deposition mask may be displaced or deformed relative to the frame body after welding.

### Solution to Problem

A mask sheet according to one aspect of the disclosure includes a mask sheet for vapor deposition having a first direction as a longitudinal direction, the mask sheet including:

a grippable first side end portion; and an intermediate portion with a plurality of through-holes,

wherein the mask sheet includes, between the first side end portion and the intermediate portion,

a first narrow portion having a width which is a length in a second direction orthogonal to the first direction and smaller than the intermediate portion, or two edge patterns having a thickness smaller than a maximum thickness of the intermediate portion along two edges facing each other in the second direction.

### Advantageous Effects of Disclosure

The disclosure may reduce the likelihood that the through-holes of the mask sheet are displaced or deformed relative to the frame body after welding the mask sheet to the frame body.

### BRIEF DESCRIPTION OF DRAWINGS

FIG. 1A is a flowchart illustrating a method for manufacturing an Organic Light-Emitting Diode (OLED) panel.

FIG. 1B is a cross-sectional view illustrating a configuration of an OLED display.

FIG. 2 is a schematic view illustrating vapor depositing of manufacturing an OLED panel.

FIGS. 3A to 3D illustrate a vapor deposition mask according to a first embodiment. FIG. 3A is a plan view of a vapor deposition mask. FIG. 3B is a view of a cross section c-c of the vapor deposition mask. FIG. 3C is a view of a cross section f-f of the vapor deposition mask. FIG. 3D is a plan view illustrating a stretching technique of the mask sheet.

FIG. 4 is a flowchart illustrating a method for manufacturing a vapor deposition mask.

FIG. 5A to 5C illustrate another vapor deposition mask according to a first embodiment. FIG. 5A is a plan view of a vapor deposition mask. FIG. 5B is a view of a cross section c-c of the vapor deposition mask. FIG. 5C is a view of a cross section f-f of the vapor deposition mask.

FIG. 6A to 6C illustrate another vapor deposition mask according to a first embodiment. FIG. 6A is a plan view of a vapor deposition mask. FIG. 6B is a view of a cross section c-c of the vapor deposition mask. FIG. 6C is a view of a cross section f-f of the vapor deposition mask.

FIG. 7A to 7D illustrate a vapor deposition mask according to a second embodiment. FIG. 7A is a plan view of a vapor deposition mask. FIG. 7B is a view of a cross section c-c of the vapor deposition mask. FIG. 7C is a view of a cross section f-f of the vapor deposition mask, and FIG. 7D is a plan view illustrating a stretching technique of the mask sheet.

FIG. 8A to 8C illustrate a vapor deposition mask in the related art. FIG. 8A is a plan view of a vapor deposition mask. FIG. 8B is a view of a cross section c-c of the vapor deposition mask. FIG. 8C is a view of a cross section f-f of the vapor deposition mask.

### DESCRIPTION OF EMBODIMENTS

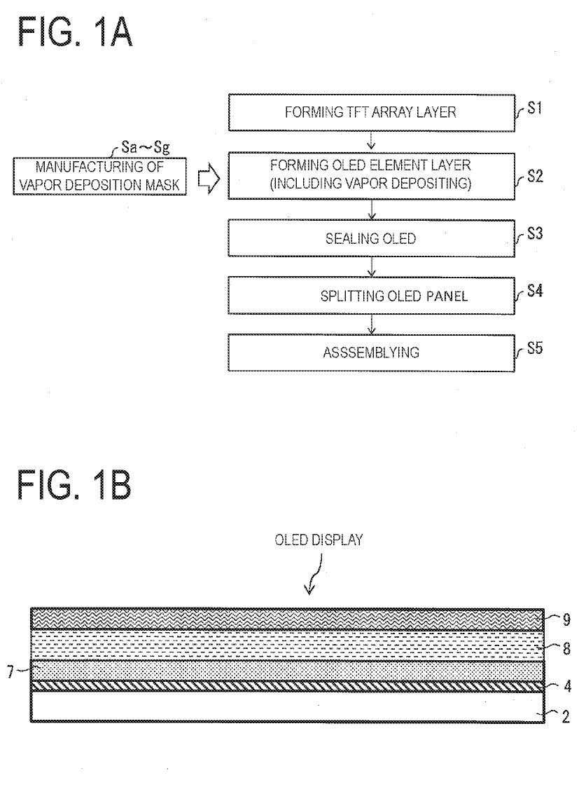

Embodiments of the disclosure will be described below with reference to FIGS. 1A to 8C. In the following description, the word “equal” is used to include cases in which elements are not completely equal, but can be said to be approximately equal or substantially equal in view of technical common sense, effects, or the like. Similarly, the word “coincide” is used to include cases in which elements do not completely coincide, but can be said to approximately coincide or substantially coincide in view of technical common sense, effects, or the like.

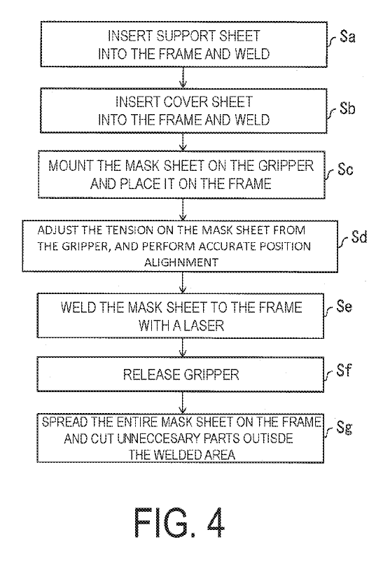

FIG. 1A is a flowchart illustrating an outline of a method for manufacturing an Organic Light-Emitting Diode (OLED) panel, and FIG. 1B is a cross-sectional view illustrating a configuration of an OLED display. As illustrated in FIGS. 1A and 1B, in Step S1, a TFT array layer 4 (for example, including a thin film transistor, a signal line, or an anode) is formed on the substrate 2. In addition, an evaporation mask may be separately manufactured (see Sa to Sg in FIG. 4, described below), and an OLED element layer 7 that includes such as a light emitting layer and a cathode may be formed in Step S2.

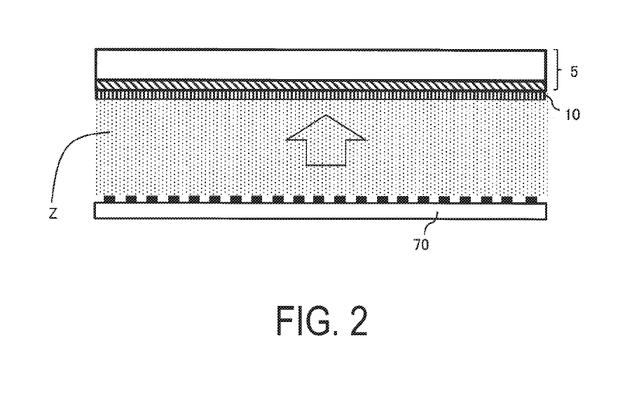

Step S2 includes vapor depositing with the vapor deposition mask. In this vapor depositing, as depicted in FIG. 2, for example, a mask sheet 10 with a plurality of through-holes may be adhered to a substrate 5 that includes a TFT array layer, and vapor deposition particles Z (for example, organic light-emitting materials) vaporized or sublimated by a vapor deposition source 70 may be vapor-deposited on the substrate 5 under vacuum conditions through the mask sheet 10 to form vapor deposition patterns corresponding to the through-holes of the mask sheet 10.

In Step S3, an OLED sealing layer 8 may be formed. In Step 4, the substrate may be divided into a plurality of OLED panels, and in Step S5, a functional layer 9 and a driver circuit having polarization and touch sensor functions may be disposed in the OLED panel to form an OLED display.

### First Embodiment

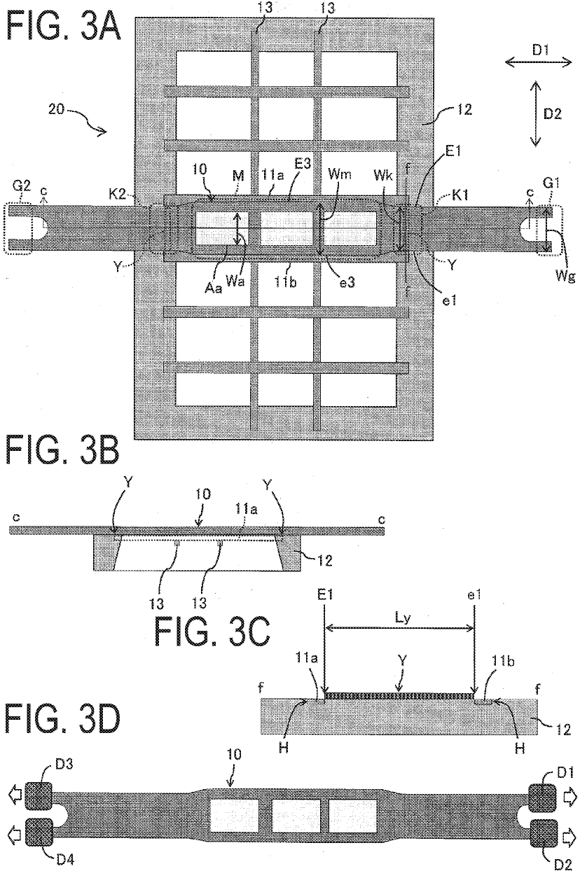

FIGS. 3A to 3D illustrate a vapor deposition mask according to a first embodiment. FIG. 3A is a plan view of a vapor deposition mask. FIG. 3B is a view of a cross section c-c of the vapor deposition mask. FIG. 3C is a view of a cross section f-f of the vapor deposition mask. FIG. 3D is a plan view illustrating a stretching technique of the mask sheet.

As illustrated in FIGS. 3A to 3D, the vapor deposition mask 20 according to the first embodiment includes a frame (frame body) 12, a plurality of cover sheets (cross-linked sheets) 11a, llb stacked in the D1 direction (lateral direction) of the frame 12, a plurality of support sheets 13 stacked in the D2 direction (longitudinal direction) of the frame 12, and a plurality of mask sheets 10. In FIGS. 3A to 3D, for convenience of explanation, only one mask sheet 10 is described, but in practice, mask sheets 10 are disposed in accordance with the number of gaps between adjacent cover sheets. In FIG. 3B, the position of the cover sheet 11a that is not included in the cross section is indicated by the dashed line.

The mask sheet 10 may be a strip-shaped vapor deposition mask sheet (a divided sheet) divided into strips, and be made of, for example, Invar material or the like, having a thickness of, for example from 10 μm to 100 μm. The mask sheet 10 includes two grippable side edges G1 and G2, and an intermediate portion M. In the intermediate portion M, a plurality of valid portions Aa in which a plurality of through-holes (vapor deposition holes) that particles to be evaporated pass through may be formed and arranged in the longitudinal direction (D1 direction). Each valid portion Aa may correspond to one OLED panel. In the mask sheet 10, the length in the direction D2 orthogonal to the direction D1 may be set as the width (sheet width) of each portion.

As illustrated in FIG. 3A, the mask sheet 10 include a narrow portion K1 between the side end portion G1 and the intermediate portion M, and a narrow portion K2 between the side end portion G2 and the intermediate portion M. The width Wk (the length in the direction D2) of the narrow portions K1 and K2 is smaller than the width Wm of the intermediate portion. For example, the two edges E1 and e1 facing each other in the direction D2 in the narrow portion K1 is located further inward in the second direction D2 than the two edges E3 and e3 facing each other in the direction D2 in the intermediate portion M.

In addition, the intermediate portion M may be composed of a valid portion Aa and an invalid portion surrounding the valid portion Aa, and the width Wg of the side end portions G1 and G2 may be smaller than the width Wm of the intermediate portion and greater than the width Wa of the valid portion.

As illustrated in FIGS. 3A to 3C, in the vapor deposition mask 20, the mask sheet 10 and the frame body 12 may be welded at the welding portion Y disposed in the narrow portions K1 and K2.

As illustrated in FIG. 3C, the welding portion Y that overlaps with the narrow portion K1, for example, may extend from one edge E1 of the two edges facing each other in the direction D2 to the other edge e1 in the narrow portion K1. In other words, the welding length Ly, which is the length of the welding portion Y in the direction D2, may be equal to the width Wk of the narrow portions K1, K2, and more specifically, be equal to the minimum width of the narrow portions K1, K2. In addition, the welding length Ly may be equal to the width Wg of the side end portions G1 and G2. Further, the welding length Ly may be equal to or greater than the width Wa of the valid portion Aa.

As illustrated in FIGS. 3A to 3C, in the mask sheet 10 of the vapor deposition mask 20, the welding portion Y is welded to the frame 12 in a state in which one edge E3 of the two edges facing each other in the direction D2 in the intermediate portion M overlaps the cover sheet 11a and the other edge e3 overlaps the cover sheet 11b. Here, the welding length Ly may be set to be less than or equal to a value obtained by subtracting, from the width Wm of the intermediate portion,

an overlap width between one edge E3 of the two edges of the intermediate portion M and the cover sheet 11a, and

an overlap width between the other edge e3 of the two edges and the cover sheet 11b.

It should be noted that each of end portions of the cover sheets 11a and 11b is inserted in the recessed portion H disposed in the frame 12 such that each of the end portions of the cover sheet 11a and 11b is not exposed from the opening of the recessed portion H, and the end portion of the support sheet 13 may also be inserted into the recessed portion below the cover sheet 11 disposed in the frame 12 such that the end portion is not exposed from the opening of the recessed portion. In this way, the support sheet 13, the cover sheets 11a and 11b, and the mask sheet 10 may be fixed (welded) to the frame 12 in this order from the vapor deposition source side.

The method for manufacturing the vapor deposition mask is as depicted in FIG. 4. As illustrated in FIGS. 3A to 3C and FIG. 4, each of end portion of the support sheet 13 may be inserted into the recessed portion disposed in the frame 12 and welded (Step Sa), and furthermore, each of the end portions of the cover sheets 11a and 11b may be inserted into the recessed portion H of the frame 12 such that each of the end portion is not exposed from the opening of the recessed portion, and welded (Step Sb).

Next, after the mask sheet on the grippers D1 are mounted to D4, the mask sheet may be arranged on the frame 12 (Step Sc). As illustrated in FIG. 3D, each of the side end portions G1 and G2 may have a shape in which the central portion is cut out. The portions located on both sides of the cutout of the side end portion G1 may be sandwiched between the grippers D1 and D2, and the portions located on both sides of the cutout of the side end portion G2 may be sandwiched between the grippers D3 and D4. Here, one edge E3 of the two edges along the longitudinal direction of the intermediate portion M may overlap the cover sheet 11a, and the other edge e3 may overlap the cover sheet 11b.

Next, the tension applied to the mask sheet may be adjusted by the grippers D1 to D4, and accurate position alignment may be performed (Step Sd).

When the position alignment is completed, the mask sheet may be welded to the frame with a laser (Step Se). In this way, as illustrated in FIG. 3C, a plurality of welding spots may be formed due to melting of the mask sheet 10 and the frame 12. Here, by forming the outermost two welding spots near the two edges E1, e1 of the mask sheet, the welding length Ly may be set to substantially coincide with the width Wk (specifically, the minimum width) of the narrow portion K1.

When the welding is completed, the grippers D1 to D4 of both side end portions G1 and G3 may be released (Step Sf). After repeating the above process and spreading the entire mask sheet on the frame 12, unnecessary portions outside of the welded portion may be cut (Step Sg).

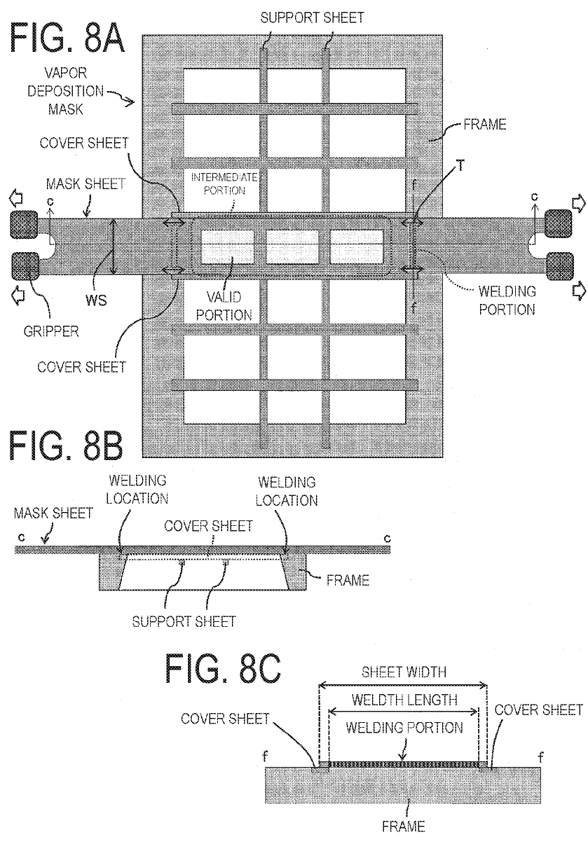

FIGS. 8A to 8C illustrate a vapor deposition mask in the related art. FIG. 8A is a plan view of a vapor deposition mask. FIG. 8B is a view of a cross section c-c of the vapor deposition mask. FIG. 8C is a view of a cross section f-f of the vapor deposition mask.

In existing vapor deposition masks, as depicted in FIG. 8A, as the width of the mask sheet is a uniform value (WS) in each part, the tension T of the gripper is applied to the four corners positioned on the end part of the cover sheet. However, as illustrated in FIG. 8B and FIG. 8C, as these four corners are located above the openings of the frame recessed portion (on the end of the cover sheet), welding cannot be performed and the welding length becomes smaller than the sheet width (WS). Accordingly, when the gripper is released after welding, the tension state of the mask sheet changes to apply inward stress to the four corners, and the position of the through-holes in the valid portion may be displaced or deformed.

In contrast, in the mask sheet 10 of the first embodiment (FIGS. 3A to 3D), the welding portion Y is disposed in the narrow portions K1 and K2, and the welding length Ly is made to substantially coincide with the width Wk (specifically, the minimum width) of the narrow portions K1 and K2 (the welding length Ly is made substantially equal to the sheet width at the welding portion Y). This may suppress changes in the tension state of the mask sheet generated when the gripper is released after welding, and therefore the possibility that the positions of the through-holes of the valid portion Aa are shifted or deformed may be reduced. This effect can be further enhanced by making the welding length Ly equal to the width Wg of the side end portions G1 and G2, or by setting the welding length Ly to be greater than or equal to the width Wa of the valid portion Aa.

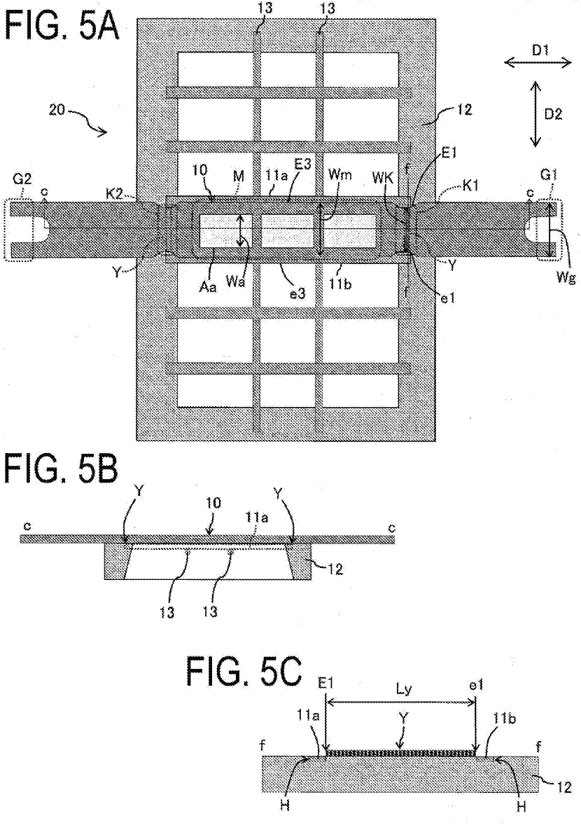

FIGS. 5A to 5C illustrate another vapor deposition mask according to the first embodiment. FIG. 5A is a plan view of a vapor deposition mask. FIG. 5B is a view of a cross section c-c of the vapor deposition mask. FIG. 5C is a view of a cross section f-f of the vapor deposition mask. In FIG. 5B, the position of the cover sheet 11a (not included in the cross section) is indicated by the dashed line.

As illustrated in FIG. 5A, the mask sheet 10 includes a constricted narrow portion K1 between the side end portion G1 and the intermediate portion M, and includes a constricted narrow portion K2 between the side end portion G2 and the intermediate portion M. The width WK of the narrow portions K1 and K2 is smaller than the width Wm of the intermediate portion. For example, the two edges E1 and e1 facing each other in the direction D2 in the narrow portion K1 may be located further inward in the second direction D2 than the two edges E3 and e3 facing each other in the direction D2 in the intermediate portion M.

In addition, the width Wg of the side end portions G1 and G2 may be equal to the width Wm of the intermediate portion and greater than the width Wa of the valid portion.

As illustrated in FIGS. 5A to 5C, in the vapor deposition mask 20, the mask sheet 10 and the frame body 12 may be welded at the welding portion Y disposed in the narrow portions K1 and K2.

As illustrated in FIGS. 5A and 5C, the welding portion Y that overlaps with the narrow portion K1, for example, may extend from one edge E1 of the two edges facing each other in the direction D2 to the other edge e1 in the narrow portion K1. That is, the welding length Ly, which is the length of the welding portion Y in the direction D2, may be approximately equal to the minimum width WK of the narrow portions K1 and K2. In addition, the welding length Ly is equal to the width Wg of the side end portions G1 and G2. Furthermore, the welding length Ly may be equal to or greater than the width Wa of the valid portion Aa.

As illustrated in FIGS. 5A to 5C, in the mask sheet 10 of the vapor deposition mask 20, the welding portion Y may be welded to the frame 12 in a state in which one edge E3 of the two edges facing each other in the direction D2 in the intermediate portion M overlaps the cover sheet 11a and the other edge e3 overlaps the cover sheet 11b. Here, the welding length Ly may be set to be less than or equal to a value obtained by subtracting, from the width Wm of the intermediate portion,

an overlap width between one edge E3 of the two edges of the intermediate portion M, and the cover sheet 11a, and

an overlap width between the other edge e3 of the two edges and the cover sheet 11b.

In this way, by providing the welding portion Y in the constricted narrow portions K1 and K2 and substantially matching the welding length Ly with the minimum width WK of the narrow portions K1 and K2 (the welding length Ly is made as close as possible to the sheet width of the welded portion Y, and substantially coincides with the sheet width), it is possible to suppress changes in the tension state of the mask sheet that occur when the gripper is released after welding and reduce the possibility that the position of the through-holes of the valid portion Aa are displaced or deformed.

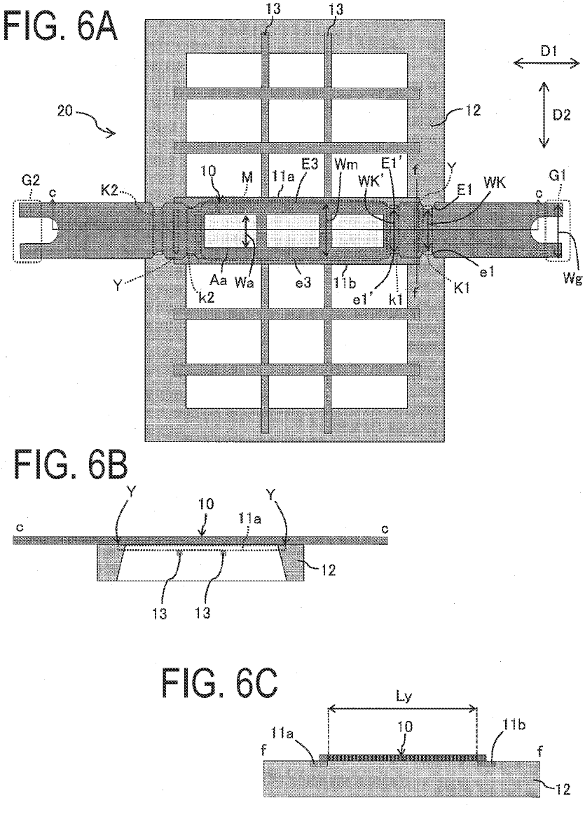

FIGS. 6A to 6C illustrate another vapor deposition mask according to a first embodiment. FIG. 6A is a plan view of a vapor deposition mask. FIG. 6B is a view of a cross section c-c of the vapor deposition mask. FIG. 6C is a view of a cross section f-f of the vapor deposition mask. In FIG. 6B, the position of the cover sheet 11a (not included in the cross section) is indicated by the dashed line.

As illustrated in FIG. 6A, the mask sheet 10 includes two constricted narrow portions K1 (side end portion side) and a narrow portion k1 (intermediate portion side) between the side end portion G1 and the intermediate portion M. In addition, two constricted narrow portions K2 (side end portion side) and a narrow portion k2 (intermediate portion side) are disposed between the side end portion G2 and the intermediate portion M.

The width Wk of the narrow portions K1 and K2, and the width WK′ of the narrow portions k1 and k2 are smaller than the width Wm of the intermediate portion M. For example, the two edges E1 and e1 facing each other in the direction D2 in the narrow portion K1 may be located further inward in the second direction D2 than the two edges E3 and e3 facing each other in the direction D2 in the intermediate portion M, and the two edges El′ and e1′ facing each other in the direction D2 in the narrow portion k1 may be located further inward in the second direction D2 than the two edges E3 and e3 facing each other in the direction D2.

The width Wg of the side end portions G1 and G2 may be equal to the width Wm of the intermediate portion and greater than the width Wa of the valid portion.

As illustrated in FIGS. 6A to 6C, in the vapor deposition mask 20, the mask sheet 10 and the frame body 12 are welded to each other at the welding portion Y disposed between the two narrow portions K1 and k1 and the welding portion Y disposed between the two narrow portions K2 and k2.

As illustrated in FIG. 6A and FIG. 6C, the welding length Ly, which is the length of the welding portion Y in the direction D2, may be equal to the minimum width WK of the narrow portion K1 and the minimum width Wk′ of the narrow portion k1. In addition, the welding length Ly may be smaller than the width Wg of the side end portions G1 and G2. Further, the welding length Ly may be equal to or greater than the width Wa of the valid portion Aa.

As illustrated in FIGS. 6A to 6C, in the mask sheet 10 of the vapor deposition mask 20, the welding portion Y may be welded to the frame 12 in a state in which one edge E3 of the two edges facing each other in the direction D2 in the intermediate portion M overlaps the cover sheet 11a and the other edge e3 overlaps the cover sheet 11b. Here, the welding length Ly may be set to be less than or equal to a value obtained by subtracting,

from the width Wm of the intermediate portion,

an overlap width between one edge E3 of the two edges of the intermediate portion M, and

the cover sheet lla and an overlap width between the other edge e3 of the two edges and the cover sheet 11b.

In the mask sheet 10 of FIGS. 6A to 6C, although the welding length Ly is smaller than the sheet width at the welding portion Y, by providing two narrow portions K1, k1 or K2, k2) on both sides of the welding portion Y in the D1 direction, the tension applied to the portion located further outside the welding portion Y as viewed in the D2 direction can be made as small as possible, and it is possible to suppress changes in the tension state of the mask sheet that occur when the gripper is released after welding.

It should be noted that in a case where Ly is made greater than WK and Wk′ the external stress of the welding portion Y can be effectively reduced, in a case where Ly is made smaller than WK and Wk′ the external stress of the welding portion y can be effectively reduced when the mask sheet 10 is relatively thin, and in a case where Ly is made greater than WK and smaller than WK′, it is possible to reduce the external stress of the welding portion Y while maintaining the rigidity of the mask sheet 10.

In the first embodiment, although the cover sheets 11a and 11b are positioned further on the upper side (the mask sheet side) than the supports sheets 13, it is also possible to invert the vertical relationship between the cover sheets and the support sheets (the support sheets may be on the upper side), and the same effect as described above can be obtained in this case as well.

### Second Embodiment

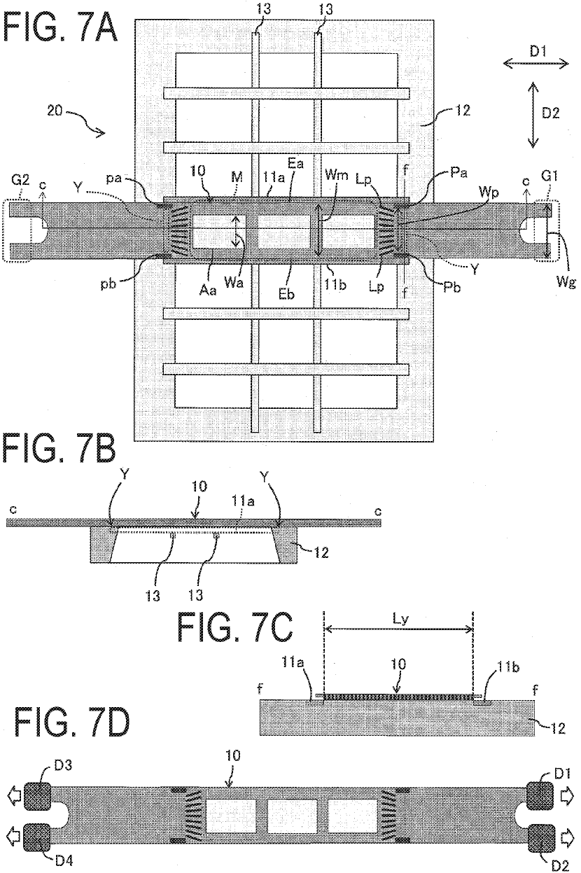

FIGS. 7A to 7D illustrate a vapor deposition mask according to a second embodiment. FIG. 7A is a plan view of a vapor deposition mask. FIG. 7B is a view of a cross section c-c of the vapor deposition mask. FIG. 7C is a view of a cross section f-f of the vapor deposition mask. FIG. 7D is a plan view illustrating a stretching technique of the mask sheet. In FIG. 7B, the position of the cover sheet 11a (not included in the cross section) is indicated by the dashed line.

In the mask sheet 10 of the second embodiment, as illustrated in FIG. 7, two edge patterns Pa, pb having a thickness less than the maximum thickness of the intermediate portion M are formed between the side end portion G1 and the intermediate portion M along two sheet edges Ea and Eb facing each other in the width direction, and two edge patterns pa, pb having a thickness less than the maximum thickness of the intermediate portion M are formed between the side end portion G2 and the intermediate portion M along the two sheet edges Ea and Eb facing each other in the width direction.

The interval Wp between the two edge patterns (Pa, Pb or pa, pb) may be greater than the width Wa of the valid portion. In addition, the width Wg of the side end portions G1 and G2 may be equal to the width Wm of the intermediate portion, and greater than the width Wa of the valid portion.

As illustrated in FIGS. 7A to 7C, in the vapor deposition mask 20, the mask sheet 10 and the frame body 12 are welded to each other at the welding portion Y disposed between the two edge patterns Pa and Pb and the welding portion Y disposed between the two edge patterns pa and pb.

As illustrated in FIG. 7A and FIG. 7C, the welding length L, which is the length of the welding portion y in the direction D2, may be equal to the interval Wp between the two edge patterns (Pa, pb, or pa, pb) and may be less than the width Wg of the side end portions G1, G2 and the width Wm of the intermediate portion M.

As illustrated in FIGS. 7A to 7C, in the mask sheet 10 of the vapor deposition mask 20, the welding portion Y may be welded to the frame 12 in a state in which one edge Ea of the two edges facing each other in the direction D2 in the intermediate portion M overlaps the cover sheet 11a and the other edge Eb overlaps the cover sheet 11b. Here, the welding length Ly may be set to be less than or equal to a value obtained by subtracting,

from the width Wm of the intermediate portion,

an overlap width between one edge Ea of the two edges of the intermediate portion M, and

the cover sheet 11a and an overlap width between the other edge Eb of the two edges and the cover sheet 11b.

In the mask sheet 10 of FIGS. 7A to 7C, although the welding length Ly is smaller than the sheet width at the welding portion Y, by providing two edge patterns (Pa, Pb or pa, pb) on both sides of the welding portion Y in the D1 direction, the tension applied to the portion located further outside the welding portion Y as viewed in the D2 direction can be decreased, and it is possible to suppress changes in the tension state of the mask sheet that occur when the grippers D1 to D4 of FIG. 7D are released.

Further, in the mask sheet 10 of the second embodiment, as a plurality of line patterns Lp having a thickness less than the maximum thickness of the intermediate portion M are disposed between the welding portion Y and the intermediate portion M such that the plurality of line patterns extend radially toward the intermediate portion M, it is possible to further suppress changes in the tension state of the mask sheet that occur when the gripper is released after welding. It should be noted that it is sufficient for the thickness of the line pattern Lp be less than the maximum thickness of the intermediate portion M, and it may also be a slit shape (a state where it is completed penetrated and has no thickness).

### Supplement

A mask sheet according to a first embodiment is a mask sheet for vapor deposition having a first direction (D1) as a longitudinal direction, a grippable first side end portion (G1), and an intermediate portion (M) with a plurality of through-holes, wherein the mask sheet includes, between the first side end portion and the intermediate portion, a first narrow portion (K1) having a width (Wk) which is a length in a second direction (D2) orthogonal to the first direction and smaller than the intermediate portion, or two edge patterns (Pa, Pb) having a thickness smaller than a maximum thickness of the intermediate portion along two edges (Ea, Eb) facing each other in the second direction.

In a second aspect, two edges (E1, e1) facing each other in the second direction in the first narrow portion are located further inward in the second direction than the two edges (E3, e3) facing each other in the second direction in the intermediate portion.

In a third aspect, the intermediate portion includes a valid portion (Aa) with a plurality of through-holes formed in the intermediate portion, and an invalid portion surrounding the valid portion.

In a fourth aspect, the width (Wg) of the first side end portion is smaller than a width (Wm) of the intermediate portion and greater than a width (Wa) of the valid portion.

In a fifth aspect, the first narrow portion has a constricted shape, and a minimum width (WK) of the first narrow portion is greater than a width (Wa) of the valid portion and smaller than a width (Wg) of the first side end portion.

In a sixth aspect, a plurality of line patterns (Lp) having a thickness smaller than a maximum thickness of the intermediate portion are disposed between the first side end portion and the intermediate portion the plurality of line patterns extend radially toward the intermediate portion.

In a seventh aspect, an interval (Wp) between the two edge patterns is greater than a width (Wa) of the valid portion.

In an eighth aspect, a second narrow portion (K2) is disposed between a grippable second side end portion (G2) and the intermediate portion that has a width smaller than that of the intermediate portion, or two edge patterns (pa, pb) having a thickness smaller than the maximum thickness of the intermediate portion is disposed along two edges (Ea, Eb) facing each other in the second direction.

In a ninth aspect, the plurality of through-holes are vapor deposition holes that particles to be evaporated pass through.

In a tenth aspect, the vapor deposition mask includes the mask sheet (10), and a frame body that the mask sheet is fixed to.

In an eleventh aspect, the mask sheet and the frame body are welded to each other at a welding portion (Y) disposed at the first narrow portion or at a welding portion (Y) disposed between the two edge patterns.

In a twelfth aspect, a length (Ly) of the welding portion in the second direction is equal to the width of the first narrow portion.

In a thirteenth aspect, a length of the welding portion in the second direction is equal to a minimum width of the first narrow portion.

In a fourteenth aspect, a length of the welding portion in the second direction is equal to a width of the first side end portion.

In a fifteenth aspect, a length of the welding portion in the second direction is equal to or greater than a width of the valid portion disposed in the intermediate portion.

In a sixteenth aspect, a first crosslinked sheet (11a) and a second crosslinked sheet (11b) crossing the frame body are disposed, wherein one (E3) of the two edges facing each other in the second direction in the intermediate portion overlaps the first crosslinked sheet and the other (e3) overlaps the second crosslinked sheet.

In a seventeenth aspect, the length of the welding portion in the second direction is set to be less than or equal to a value obtained by subtracting, from the width of the intermediate portion,

an overlap width of one of the two edges of the intermediate portion and the first crosslinked sheet, and

an overlap width of the other of the two edges of the intermediate portion and the second crosslinked sheet.

In an eighteenth aspect, each of end portions of the first crosslinked sheet and the second crosslinked sheet is inserted into a recessed portion disposed in the frame body such that each of the end portions is not exposed from an opening of the recessed portion.

A nineteenth aspect for manufacturing a display panel includes vapor depositing with the vapor deposition mask.

The disclosure is not limited to each of the embodiments described above, and embodiments obtained by appropriately combining technical methods disclosed in different embodiments are also included in the technical scope of the disclosure. Moreover, novel technical features may be formed by combining the technical approaches stated in each of the embodiments.

### REFERENCE SIGNS LIST

10 Mask sheet
11a, 11b Cover sheet
12 Frame
20 Vapor deposition mask
M Intermediate portion
G1, G2 Side end portion
D1 to D4 Gripper
H Recessed portion (of the frame)
K1, K2, k1, k2 Narrow portion
Aa Valid portion
Pa, Pb, pa, pb Edge pattern
Lp Line pattern
E1, e1 Edge of narrow portion
E3, e3 Edge of

1. A mask sheet for vapor deposition having a first direction as a longitudinal direction, the mask sheet comprising:
a grippable first side end portion; and
an intermediate portion with a plurality of through-holes,
wherein the mask sheet includes, between the first side end portion and the intermediate portion,
a first narrow portion having a width being a length in a second direction orthogonal to the first direction and smaller than the intermediate portion, or
two edge patterns having a thickness smaller than a maximum thickness of the intermediate portion along two edges facing each other in the second direction.

2. The mask sheet according to claim 1,
wherein the two edges facing each other in the second direction in the first narrow portion are located further inward in the second direction than the two edges facing each other in the second direction in the intermediate portion.

3. The mask sheet according to claim 1,
wherein the intermediate portion comprises a valid portion with the plurality of through-holes formed in the intermediate portion, and an invalid portion surrounding the valid portion.

4. The mask sheet according to claim 3,
wherein a width of the first side end portion is smaller than a width of the intermediate portion and greater than a width of the valid portion.

5. The mask sheet according to claim 3,
wherein the first narrow portion has a constricted shape, and
a minimum width of the first narrow portion is greater than a width of the valid portion and smaller than a width of the first side end portion.

6. The mask sheet according to claim 1,
wherein a plurality of line patterns having a thickness smaller than a maximum thickness of the intermediate portion are disposed between the first side end portion and the intermediate portion such that the plurality of line patterns extend radially toward the intermediate portion.

7. The mask sheet according to claim 1,
wherein an interval between the two edge patterns is greater than a width of the valid portion.

8. The mask sheet according to claim 1, further comprising a second narrow portion between a grippable second side end portion and the intermediate portion that has a width smaller than that of the intermediate portion, or
two edge patterns having a thickness smaller than the maximum thickness of the intermediate portion along two edges facing each other in the second direction.

9. The mask sheet according to claim 1,
wherein the plurality of through-holes are vapor deposition holes that particles to be evaporated pass through.

10. A vapor deposition mask comprising:
the mask sheet according to claim 1, and
a frame body that the mask sheet is fixed to.

11. The vapor deposition mask according to claim 10,
wherein the mask sheet and the frame body are welded to each other at a welding portion disposed at the first narrow portion or at a welding portion disposed between the two edge patterns.

12. The vapor deposition mask according to claim 11,
wherein a length of the welding portion in a second direction is equal to the width of the first narrow portion.

13. The vapor deposition mask according to claim 12,
wherein a length of the welding portion in the second direction is equal to a minimum width of the first narrow portion.

14. The vapor deposition mask according to claim 11,
wherein a length of the welding portion in the second direction is equal to a width of a first side end portion.

15. The vapor deposition mask according to claim 11,
wherein a length of the welding portion in the second direction is equal to or greater than a width of a valid portion disposed in an intermediate portion.

16. The vapor deposition mask according to claim 11, further comprising a first crosslinked sheet and a second crosslinked sheet crossing the frame body,
wherein one of the two edges facing each other in the second direction in the intermediate portion overlaps the first crosslinked sheet and the other overlaps the second crosslinked sheet.

17. The vapor deposition mask according to claim 16,
wherein a length of the welding portion in the second direction is set to be less than or equal to a value obtained by subtracting, from a width of the intermediate portion,
an overlap width of one of the two edges of the intermediate portion and the first crosslinked sheet, and
an overlap width of the other of the two edges of the intermediate portion and the second crosslinked sheet.

18. The vapor deposition mask according to claim 16,
wherein each of end portions of the first crosslinked sheet and the second crosslinked sheet is inserted into a recessed portion disposed in the frame body such that each of the end portion is not exposed from an opening of the recessed portion.

19. A method for manufacturing a display panel, the method comprising vapor depositing with the vapor deposition mask according claim 10.

20. The mask sheet according to claim 2,
wherein the plurality of through-holes are vapor deposition holes that particles to be evaporated pass through.
